(19) United States
(12) Patent Application Publication
(10) Pub. No.: US 2013/0037866 A1
(43) Pub. Date: Feb. 14, 2013

(54) METHOD OF FORMING A SEMICONDUCTOR DEVICE

(71) Applicants: Hans-Jürgen Thees, Dresden (DE); Roman Boschke, Dresden (DE); Ralf Otterbach, Dresden (DE)

(72) Inventors: Hans-Jürgen Thees, Dresden (DE); Roman Boschke, Dresden (DE); Ralf Otterbach, Dresden (DE)

(73) Assignee: GLOBALFOUNDRIES INC., Grand Cayman (KY)

(21) Appl. No.: 13/209,061

(22) Filed: Aug. 12, 2011

(51) Int. Cl. H01L 21/28; H01L 29/78

(52) U.S. Cl. 257/288; 438/595; 257/E21.19; 257/E29.255

(57) ABSTRACT

A method for forming a semiconductor device includes providing a substrate and depositing a gate stack having a side periphery on the substrate. A first liner dielectric layer is deposited on the substrate and the gate stack. A first spacer dielectric layer is deposited on the first liner dielectric layer. The first spacer dielectric layer is selectively etched such that the first spacer dielectric layer remains adjacent at least a portion of the side periphery of the gate stack. A first resist mask is disposed on a first portion of the first spacer dielectric layer such that the first portion of the first spacer dielectric layer is protected by the resist mask and a second portion of the first spacer dielectric layer is not protected by the resist mask. The first spacer dielectric layer is etched such that the second portion is removed and the first portion remains.

### FIELD OF THE INVENTION

The present invention generally relates to a method of forming a semiconductor device and more particularly relates to a method of forming gates of a metal-oxide-semiconductor field-effect transistor (“MOSFET”).

### BACKGROUND OF THE INVENTION

In one common technique of MOSFET formation, a gate stack is deposited on a substrate. A dielectric spacer is then formed around a gate stack by first depositing a dielectric then selectively etching the dielectric using a reactive-ion etching (“RIE”) process. This process may then be repeated to add additional thickness of the spacer. This results in a spacer that is generally symmetrical about the gate. Furthermore, the process of depositing the dielectric may result in an uncontrolled, variable thickness of the gate spacer. Specifically, when numerous lines of gates are involved, an outer line of gates receives a spacer having a larger thickness than the other lines. This situation is typically undesirable, but could be advantageous if properly controlled. Lastly, the typical sequence of dielectric deposition and RIE process leads to a recess in the substrate. Said another way, the multiple RIE processes will consume silicon of the substrate in the active region of the MOSFET. This will lead to performance degradation of the MOSFET.

In some instances, it is desirable to form a transistor with a gate having an asymmetric dielectric gate spacer. In addition, it may be desirable to form multiple gates with different spacer thicknesses. It is further desirable to have minimal recessing of the silicon adjacent the spacers.

Moreover, other desirable features and characteristics of the present invention will become apparent from the subsequent detailed description of the invention and the appended claims, taken in conjunction with the accompanying drawings and this background of the invention.

### BRIEF SUMMARY OF THE INVENTION

In one aspect of the invention, a method is provided for forming a semiconductor device. The method includes providing a substrate and depositing a gate stack having a side periphery on the substrate. The method further includes depositing a first liner dielectric layer on the substrate and the gate stack. A first spacer dielectric layer is deposited on the first liner dielectric layer. The method also includes selectively etching the first spacer dielectric layer such that the first spacer dielectric layer remains adjacent at least a portion of the side periphery of the gate stack. A first resist mask is disposed on a first portion of the first spacer dielectric layer such that the first portion of the first spacer dielectric layer is protected by the resist mask and a second portion of the first spacer dielectric layer is not protected by the resist mask. The method further includes etching the first spacer dielectric layer such that the second portion is removed and the first portion remains.

In another aspect of the invention, a method is provided for forming a semiconductor device. The method includes providing a substrate and depositing first and second gate stacks on the substrate. Each gate stack has a side periphery. The method further includes depositing a first liner dielectric layer on the substrate and the gate stacks. A first spacer dielectric layer is deposited on the first liner dielectric layer. The method also includes selectively etching the first spacer dielectric layer such that the first spacer dielectric layer remains adjacent at least a portion of each of the side peripheries of the gate stacks. A first resist mask is disposed on the first spacer dielectric layer deposited on the first gate stack such that the first spacer dielectric layer adjacent the side periphery of the first gate stack is protected and the first spacer dielectric layer deposited on the second gate stack is not protected. The method further includes etching the first spacer dielectric layers such that the first spacer dielectric layer deposited on the second gate stack is removed.

### BRIEF DESCRIPTION OF THE DRAWINGS

The present invention will hereinafter be described in conjunction with the following drawing figures, wherein like numerals denote like elements, and

FIG. 1 shows a cross-sectional side view of a semiconductor device after depositing of gate stacks on a substrate;

FIG. 2 shows a cross-sectional side view of the semiconductor device after depositing a first liner dielectric layer on the substrate and the gate stacks;

FIG. 3 shows a cross-sectional side view of the semiconductor device after depositing first spacer dielectric layer on the first liner dielectric layer;

FIG. 4 shows a cross-sectional side view of the semiconductor device after selectively etching the first spacer dielectric layer;

FIG. 5 shows a cross-sectional side view of the semiconductor device after disposing a first resist mask on at least a portion of the first spacer dielectric layer;

FIG. 6 shows a cross-sectional side view of the semiconductor device after etching the first spacer dielectric layer with the first resist mask in place;

FIG. 7 shows a cross-sectional side view of the semiconductor device after depositing a second liner dielectric layer on the first liner dielectric layer and the first spacer dielectric layer;

FIG. 8 shows a cross-sectional side view of the semiconductor device after depositing a second spacer dielectric layer on the second liner dielectric layer;

FIG. 9 shows a cross-sectional side view of the semiconductor device after selectively etching the second spacer dielectric layer;

FIG. 10 shows a cross-sectional side view of the semiconductor device after disposing a second resist mask on at least a portion of the second spacer dielectric layer;

FIG. 11 shows a cross-sectional side view of the semiconductor device after etching the second spacer dielectric layer with the second resist mask in place; and

FIG. 12 shows a cross-sectional side view of the semiconductor device after etching the first and second liner dielectric layers.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Referring to the Figures, wherein like numerals indicate like parts throughout the several views, a method of forming a semiconductor device 20 is shown and described herein. The semiconductor device 20 of the illustrated embodiment includes transistors 22, specifically metal-oxide-semiconductor field-effect transistors (MOSFETs). More specifically, the MOSFETs may be p-type and n-type MOSFETs as is typically found in a complementary metal-oxide-semiconductor (CMOS) device.

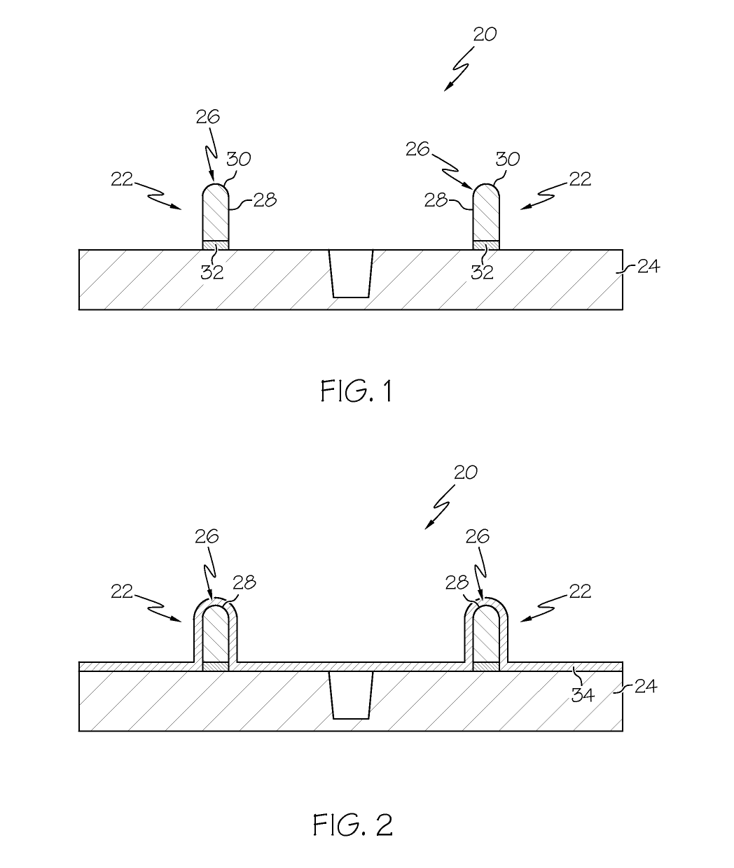

Referring to FIG. 1, the semiconductor device includes a substrate 24. In the illustrated embodiment, the substrate 24 includes silicon (Si), however other suitable semiconductor surface materials are well known to those skilled in the art. Those skilled in the art realize that the substrate 24 is doped to create sources (not shown) and drains (not shown) for the associated transistors 22. Furthermore, the semiconductor device 20 may include a very high number of transistors 22 and associated logic and storage elements (not separately numbered). However, for the purposes of simplicity in describing the device 20 and method, only a limited number of transistors 22 are shown.

Still referring to FIG. 1, the method includes depositing a gate stack 26 on the substrate 24 for each transistor 22. The gate stack 26 may be formed from one or more materials, including, but not limited to, metals and polycrystalline silicon (“polysilicon” or “polySi”), as is readily appreciated by those skilled in the art. The gate stack 26 includes a side periphery 28. The side periphery 28 of the illustrated embodiment extends between a top 30 and a bottom 32 of the gate stack 26.

The method also includes depositing a first liner dielectric layer 34 on the substrate 24 and the gate stack 26, as shown in FIG. 2. The first liner dielectric layer 34 of the illustrated embodiment comprises silicon nitride applied using a conformal process. In the illustrated embodiment, the first liner dielectric layer 34 has a thickness of about 5 nm. However, other suitable materials, processes, and thicknesses may alternatively be utilized.

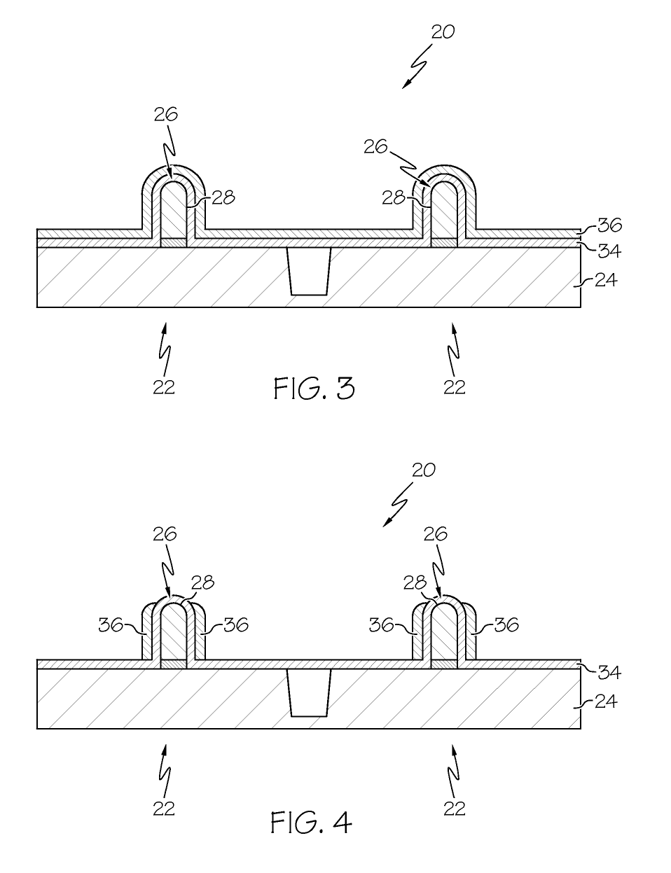

Referring now to FIG. 3, the method further includes depositing a first spacer dielectric layer 36 on the first liner dielectric layer 34. The first spacer dielectric layer 36 of the illustrated embodiment comprises silicon oxide applied using a conformal process. The thickness of the first spacer dielectric layer 36 may be chosen based on the end use of the transistor 22, as realized by those skilled in the art.

The method also includes selectively etching the first spacer dielectric layer 36. The etching is done with a high selectivity process, which prevents removal of the first liner dielectric layer 34. More specifically, in one embodiment, the selective etching of the first spacer dielectric layer 36 is performed with a reactive-ion etching (“RIE”) process. The etching results in the first spacer dielectric layer 36 remaining in place adjacent at least a portion of the side periphery 28 of the gate stack 26, as is shown in FIG. 4. Said another way, the etching removes the first spacer dielectric layer 36 from horizontal surfaces (not numbered) and leaves it on vertical surfaces (not numbered).

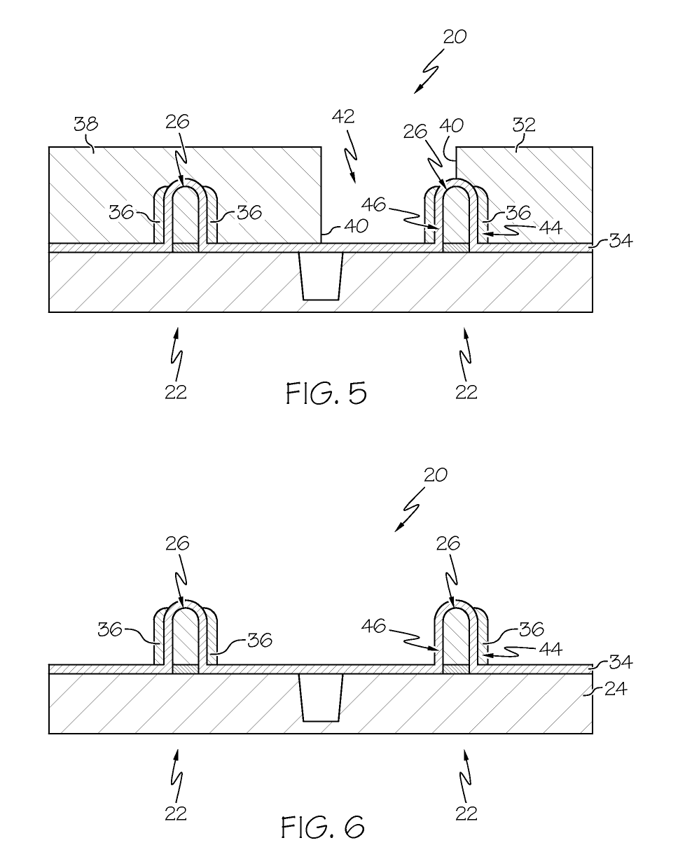

Referring now to FIG. 5, the method further includes disposing a first resist mask 38 on the semiconductor device 20. The first resist mask 38 includes at least one edge 40 defining at least one void 42. The void 42 or voids 42 define the region(s) (not numbered) of the device 20 that are to be etched. Said plainly, the first resist mask 38 protects the device 20 from etching while the voids 42 of the first resist mask 38 permit etching of the device 20. To form a symmetric gate, the first resist mask 38 covers and protects the entire gate stack 26.

To form an asymmetric gate, the first resist mask 38 covers only a portion of the gate stack 26. Said another way, the edge 40 of the first resist mask 38 is disposed atop the gate stack 26 such that part of the gate stack 26 is exposed by the void 42 and part of the gate stack 26 is protected by the first resist mask 38. As such, a first portion 44 of the first spacer dielectric layer 36 is protected by the first resist mask 38 and a second portion 46 of the first spacer dielectric layer 36 is not protected by the first resist mask 38.

The method also includes etching the first spacer dielectric layer 36 such that the second portion 46 is removed and the first portion 44 remains. In the illustrated embodiment, this etching is done with a wet etch process. That is, a chemical etchant is applied to device 20 which removes the first spacer dielectric layer 36 that is not protected by the first resist mask 38. As can be seen with reference to FIG. 5 and FIG. 6, the first portion 44 of the first spacer dielectric layer 36 remains while the second portion 46 is removed. The first liner dielectric layer 34 protects the substrate 24 during this etching process.

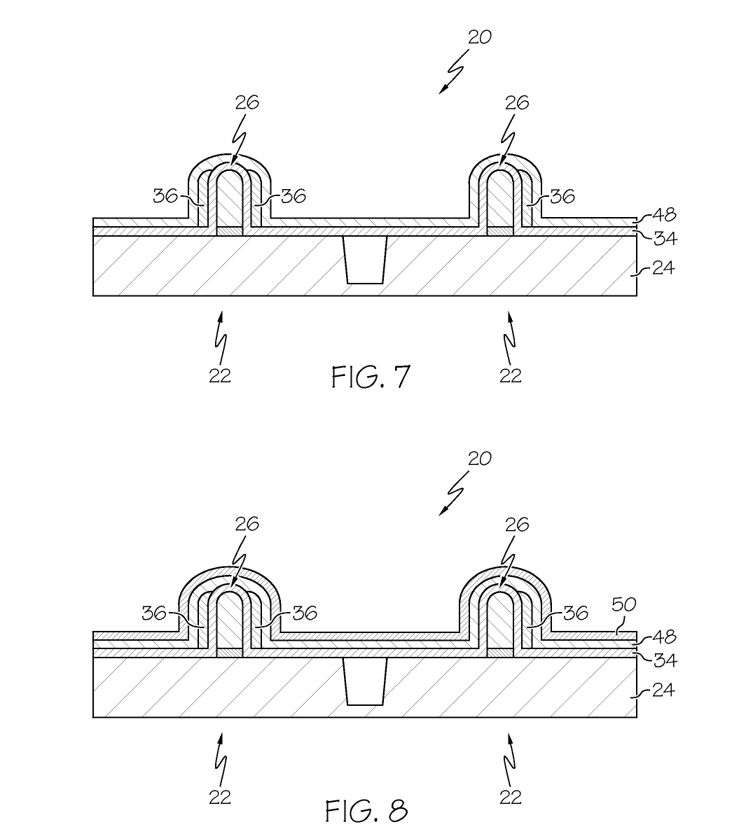

The method may further include depositing a second liner dielectric layer 48, as shown in FIG. 7. Specifically, the second liner dielectric layer is deposited on the first liner dielectric layer 34 and the first spacer dielectric layer 36, i.e., the portions of the first spacer dielectric layer 36 that remain after the etching process. As with the first liner dielectric layer 34, the second liner dielectric layer 48 of the illustrated embodiment comprises SiN applied using a conformal process. In the illustrated embodiment, the second liner dielectric layer 48 has a thickness of about 5 nm. However, other suitable materials, processes, and thicknesses may alternatively be utilized.

Referring now to FIG. 8, the method may also include depositing a second spacer dielectric layer 50 on the second liner dielectric layer 48. The second spacer dielectric layer 50 of the illustrated embodiment includes silicon oxide applied using a conformal process. The thickness of the second spacer dielectric layer 50 may be chosen based on the end use of the transistor 22, as realized by those skilled in the art. However, in the illustrated embodiment, the thickness of the second spacer dielectric layer 50 is greater than the thickness of the first space dielectric layer 36.

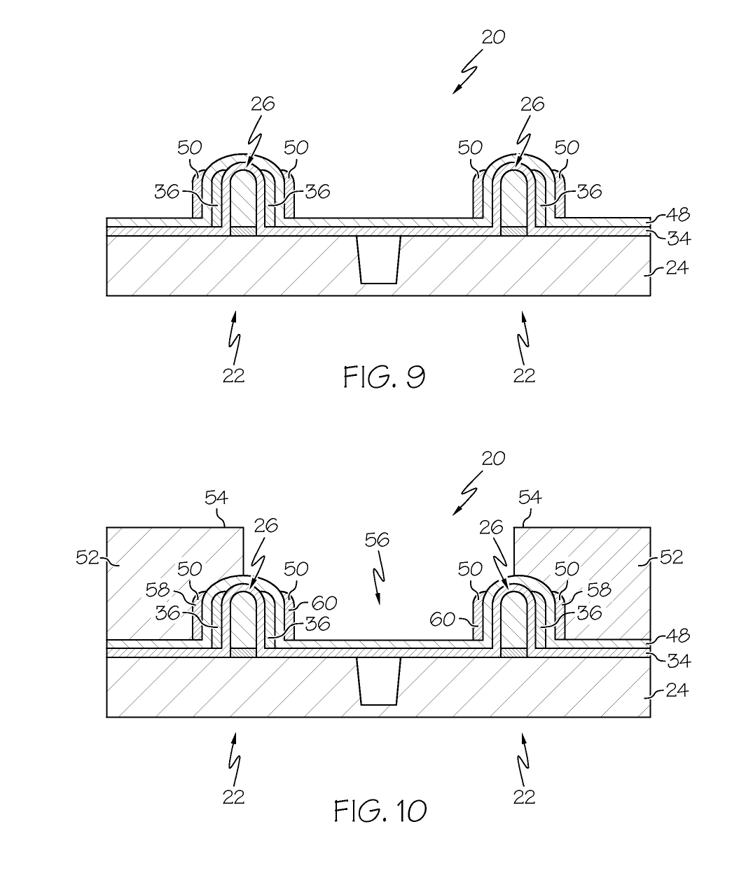

The method may further include selectively etching the second spacer dielectric layer 50 such that the second spacer dielectric layer 50 remains adjacent at least a portion of the side periphery 28 of the gate stack 26, as shown in FIG. 9. The etching is done with a high selectivity process, which prevents removal of the first and second liner dielectric layers 34, 48. More specifically, in one embodiment, the selective etching of the second spacer dielectric layer 50 is performed with an RIE process. The etching removes the second spacer dielectric layer 50 from horizontal surfaces (not numbered) and leaves it on vertical surfaces (not numbered).

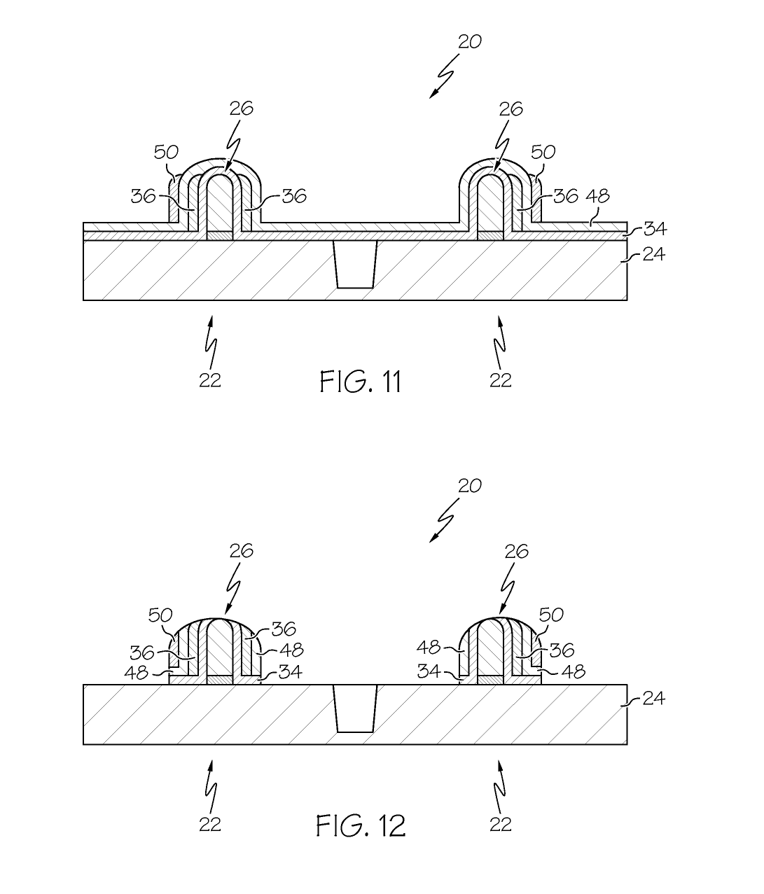

Referring now to FIG. 11, the method further includes disposing a second resist mask 52 on the semiconductor device 20. As with the first resist mask 38 described above, the second resist mask 52 includes at least one edge 54 defining at least one void 56 defining the region(s) (not numbered) of the device 20 that are to be etched. To form a symmetric gate, the second resist mask 52 covers and protects the entire gate stack 26. To form an asymmetric gate, the second resist mask 52 covers only a portion of the gate stack 26, i.e., the edge 54 of the second resist mask 52 is disposed atop the gate stack 26 such that part of the gate stack 26 is exposed by the void 42 and part of the gate stack 26 is protected by the second resist mask 52. As such, a first portion 58 of the second spacer dielectric layer 50 is protected by the second resist mask 52 and a second portion 60 of the second spacer dielectric layer 50 is not protected by the second resist mask 52.

The method may also include etching the second spacer dielectric layer 50 such that the second portion 60 is removed and the first portion 58 remains. In the illustrated embodiment, this etching is done with a wet etch process. That is, a chemical etchant is applied to device 20 which removes the second spacer dielectric layer 50 that is not protected by the second resist mask 52. As can be seen with reference to FIG. 11 and FIG. 12, the first portion 58 of the second spacer dielectric layer 50 remains while the second portion 60 is removed. The first and second liner dielectric layers 34, 48 protect the substrate 24 during this etching process.

The method also includes etching the liner dielectric layers 34, 48. If applying the second liner and spacer dielectric layers 48, 50 is not desired, this etching may occur after the etching of the first spacer dielectric layer 36 with the first resist mask 38. As such, only the first liner dielectric layer 24 would be etched, as the second liner dielectric layer 48 is not applied. Otherwise, this etching of both liner dielectric layers 34, 48 may occur after the etching of the second spacer dielectric layer 50 with the second resist mask 52, as is shown in FIG. 12. In either case, the etching of the liner dielectric layers 34, 48 is done with an RIE process with high selectivity to silicon. This etching will cause only a small loss to the silicon of the substrate 24, especially when compared to multiple RIE process recursions of the prior art. Furthermore, the recess formed to the silicon of the substrate 24 around an asymmetrical dielectric is comparable, i.e., nearly equal, to the recess formed to the silicon of the substrate 24 around a symmetrical dielectric.

The methods described herein may be applied to form transistors 22 with gate stacks 26 having up to ten different dielectric thicknesses and configurations. Importantly, these transistors 22 may be formed in combination on a single device 20. Specifically, transistors 22 with four different symmetric dielectric thicknesses may be realized utilizing the methods described herein. These four different symmetric dielectric thicknesses include: (a) all four dielectric layers 34, 36, 48, 50 forming a sidewall spacer for the gate stack 26; (b) both liner dielectric layers 34, 48 and the first spacer dielectric layer 36 forming a sidewall spacer for the gate stack 26; (c) both liner dielectric layers 34, 48 and the second spacer dielectric layer 50 forming a sidewall spacer for the gate stack 26, and (d) both liner dielectric layers 34, 48 forming a sidewall spacer for the gate stack 26. Gate stacks 26 with symmetric dielectrics may be utilized in transistors 22 for standard logic circuits, low power logic circuits, dynamic random-access memory (“DRAM”) circuits, and high-voltage circuit applications. Particularly, these different types of circuits may be easily combined on one chip (not shown) with different spacer thicknesses.

Furthermore, transistors 22 with six different asymmetric spacer thicknesses may be realized utilizing the methods described herein in accordance with the following table:

| First Side | Second Side |
|---|---|
| All four dielectric layers 34, | First and second liner dielectric layers |
| 36, 48, 50 | 34, 48 and first spacer dielectric layer |
| | 36 |
| All four dielectric layers 34, | First and second liner dielectric layers |
| 36, 48, 50 | 34, 48 and second spacer dielectric |
| | layer 50 |
| All four dielectric layers 34, | First and second liner dielectric layers |
| 36, 48, 50 | 34, 48 |
| First and second liner | First and second liner dielectric layers |
| dielectric layers 34, 48 and | 34, 48 and second spacer dielectric |
| first spacer dielectric layer 36 | layer 50 |
| First and second liner | First and second liner dielectric layers |
| dielectric layers 34, 48 and | 34, 48 |
| first spacer dielectric layer 36 | |
| First and second liner | First and second liner dielectric layers |
| dielectric layers 34, 48 and | 34, 48 |
| second spacer dielectric layer 50 | |

The transistors 22 with asymmetric gate spacers may be utilized for coping with high voltages on the sources and drains. The transistors 22 with asymmetric gate spacers may also be used in conjunction with self-aligned contact etching processes. In these processes, enhanced protection against contact to gate 26 shorts is needed where standard thickness of gate spacers may result in such undesirable shorts.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method of forming a semiconductor device, said method comprising:
providing a substrate;
depositing a gate stack having a side periphery on the substrate;
depositing a first liner dielectric layer on the substrate and the gate stack;
depositing a first spacer dielectric layer on the first liner dielectric layer;
selectively etching the first spacer dielectric layer such that the first spacer dielectric layer remains adjacent at least a portion of the side periphery of the gate stack;
disposing a first resist mask on a first portion of the first spacer dielectric layer such that the first portion of the first spacer dielectric layer is protected by the resist mask and a second portion of the first spacer dielectric layer is not protected by the resist mask; and
etching the first spacer dielectric layer such that the second portion is removed and the first portion remains.

2. A method as set forth in claim 1 further comprising removing the first resist mask.

3. A method as set forth in claim 2 further comprising depositing a second liner dielectric layer on the first liner dielectric layer and the first spacer dielectric layer.

4. A method as set forth in claim 3 further comprising depositing a second spacer dielectric layer on the second liner dielectric layer.

5. A method as set forth in claim 4 further comprising selectively etching the second spacer dielectric layer such that the second spacer dielectric layer remains adjacent at least a portion of the side periphery of the gate stack.

6. A method as set forth in claim 5 further comprising disposing a second resist mask on a first portion of the second spacer dielectric layer such that the first portion of the second spacer dielectric layer is protected by the resist mask and a second portion of the second spacer dielectric layer is not protected by the resist mask.

7. A method as set forth in claim 6 further comprising etching the second spacer dielectric layer such that the second portion is removed and the first portion remains.

8. A method as set forth in claim 7 further comprising etching the first and second liner dielectric layers to expose the substrate.

9. A method as set forth in claim 1 further comprising etching the first liner dielectric layer to expose the substrate.

10. A method as set forth in claim 1 wherein depositing a first liner dielectric layer comprises depositing silicon nitride on the substrate and the gate stack.

11. A method as set forth in claim 1 wherein depositing a first spacer dielectric layer comprises depositing silicon oxide on the substrate and the gate stack.

12. A method as set forth in claim 1 wherein selectively etching the first spacer dielectric layer is further defined as etching the first spacer dielectric layer with reactive-ion etching (“RIE”) such that the first spacer dielectric layer remains adjacent at least a portion of the side periphery of the gate stack.

13. A method of forming a semiconductor device, said method comprising:
providing a substrate;
depositing a first gate stack and a second gate stack on the substrate wherein each gate stack has a side periphery;
depositing a first liner dielectric layer on the substrate and the gate stacks;
depositing a first spacer dielectric layer on the first liner dielectric layer;
selectively etching the first spacer dielectric layer such that the first spacer dielectric layer remains adjacent at least a portion of each of the side peripheries of the gate stacks;
disposing a first resist mask on the first spacer dielectric layer deposited on the first gate stack such that the first spacer dielectric layer adjacent the side periphery of the first gate stack is protected and the first spacer dielectric layer deposited on the second gate stack is not protected; and
etching the first spacer dielectric layers such that the first spacer dielectric layer deposited on the second gate stack is removed.

14. A method as set forth in claim 13 further comprising depositing a second liner dielectric layer on the first liner dielectric layer and the first spacer dielectric layer.

15. A method as set forth in claim 14 further comprising depositing a second spacer dielectric layer on the second liner dielectric layer.

16. A method as set forth in claim 15 further comprising selectively etching the second spacer dielectric layer such that the second spacer dielectric layer remains adjacent at least a portion of each of the side peripheries of the gate stacks.

17. A method as set forth in claim 16 further comprising disposing a second resist mask on a first portion of the second spacer dielectric layer such that the first portion of the second spacer dielectric layer is protected by the resist mask and a second portion of the second spacer dielectric layer is not protected by the resist mask.

18. A method as set forth in claim 17 further comprising disposing a second resist mask on the second spacer dielectric layer deposited on the first gate stack such that the second spacer dielectric layer adjacent the side periphery of the first gate stack is protected and the second spacer dielectric layer deposited on the second gate stack is not protected.

19. A method as set forth in claim 18 further comprising etching the second spacer dielectric layer such that the second spacer dielectric layer deposited on the second gate stack is removed.

20. A method as set forth in claim 19 further comprising etching the first and second liner dielectric layers to expose the substrate.

21. A semiconductor device comprising:
a substrate;
a first gate stack and a second gate stack disposed on the substrate, wherein each gate stack has a side periphery;
a plurality of dielectric layers disposed adjacent the side periphery of the first gate stack to form a symmetric spacer about the first gate stack;
a plurality of dielectric layers disposed adjacent the side periphery to form an asymmetric spacer about the second gate stack, wherein
a depth of a recess formed in the substrate adjacent the first gate stack is generally equal to a depth of a recess formed in the substrate adjacent the second gate stack.
